(19) United States
(12) Patent Application Publication
(10) Pub. No.: US 2025/0226319 A1
(43) Pub. Date: Jul. 10, 2025

(54) INTERCONNECT WITH TOPVIA

(71) Applicant: INTERNATIONAL BUSINESS MACHINES CORPORATION, ARMONK, NY (US)

(72) Inventors: Gideon Oyibo, Rensselaer, NY (US); Koichi Motoyama, Clifton Park, NY (US); Ruilong Xie, Niskayuna, NY (US); Tao Li, Slingerlands, NY (US); Christopher J. Penny, Saratoga Springs, NY (US); Hosadurga Shobha, Niskayuna, NY (US); Chanro Park, Clifton Park, NY (US); John Christopher Arnold, North Chatham, NY (US); Kisik Choi, Watervliet, NY (US)

(21) Appl. No.: 18/407,502

(22) Filed: Jan. 9, 2024

(51) Int. Cl. H01L 23/532; H01L 21/3213; H01L 21/768; H01L 23/522; H01L 23/528

(52) U.S. Cl. CPC H01L 23/53257; H01L 21/32133; H01L 21/76834; H01L 21/76885; H01L 23/5226; H01L 23/5283; H01L 23/5329

(57) ABSTRACT

Embodiments of present invention provide a semiconductor structure. The semiconductor structure includes a metal level on top of a supporting structure and the metal level includes a first metal line of a first type and a second metal line of a second type, where the metal line of the first type has a first section and a second section on top of the first section, the first section includes a first type of ruthenium having a first impurity level and the second section includes a second type of ruthenium having a second impurity level, the first impurity level is lower than the second impurity level, and where the second metal line of the second type includes the first type of ruthenium and is devoid of the second type of ruthenium. A method of forming the same is also provided.

### BACKGROUND

The present application relates to manufacturing of semiconductor integrated circuits. More particularly, it relates to forming interconnect with topvia and the structure formed thereby.

As semiconductor industry moves towards smaller node, due to reduced pitch size it becomes increasingly challenging to form interconnect such as metal lines and topvias. For example, as the node size reaches 1.5 nm and beyond, alternative metals are expected to be used for the minimum pitch local interconnects for wanting smaller resistivity size effect, less stringent barrier/liner need, and better reliability performance than conventional copper (Cu).

To further reduce line resistance of the alternative metal interconnect, one of the best approaches is to increase the line height of the alternative metal. However, increasing the line height in a subtractive scheme may bring several process challenges. For example, due to oxygen based etch chemistry, hard mask may swell during an etch process. Swelling of the hard mask may clog etching of the metal, causing incomplete metal etching thus resulting shorts between neighboring metal lines.

### SUMMARY

Embodiments of present invention provide a semiconductor structure. The semiconductor structure includes a metal level including a first metal line of a first type, where the first metal line of the first type has a first section and a second section on top of the first section, the first section has a first width, the second section has a second width at a top surface and a third width at a bottom surface, and the first width and the second width are larger than the third width. By having a first section underneath the second section, a different material may be used for the first section to reduce conductive resistance of the first metal line.

In one embodiment, the first section of the first metal line includes a first type of ruthenium having a first impurity level and the second section of the first metal line includes a second type of ruthenium having a second impurity level, the first impurity level being lower than the second impurity level. The use of the first type of ruthenium of a lower impurity level helps reduce the conductive resistance of the first metal line.

According to one embodiment, the semiconductor structure further includes a dielectric trench pillar and the metal level further includes a second metal line of the first type, the dielectric trench pillar being adjacent to and between the first and the second metal line, wherein the first and the second metal line are positioned mirror-symmetric with respect to the dielectric trench pillar.

In one embodiment, a height of the dielectric trench pillar is higher than a height of the first and the second metal line.

In one embodiment, the metal level further includes a second metal line of a second type that is different from the first type, the second metal line includes the first type of ruthenium and is devoid of the second type of ruthenium. The use of the first type of ruthenium, instead of the second type of ruthenium, helps reduce conductive resistance of the second metal line.

According to one embodiment, the semiconductor structure further includes a dielectric trench pillar and the metal level further includes a third metal line of the second type, the dielectric trench pillar being adjacent to and between the second and the third metal line, wherein the dielectric trench pillar has a height that is higher than a height of the second and the third metal line.

In one embodiment, the metal level further includes a third metal line of the second type and a fourth metal line of the first type, the fourth metal line being adjacent to and between the second and the third metal line.

According to one embodiment, the semiconductor structure further includes a topvia directly on top of the fourth metal line of the first type, where the topvia includes the second type of ruthenium.

According to another embodiment, the semiconductor structure further includes a topvia directly on top of the second metal line of the second type, where the topvia includes the second type of ruthenium.

Embodiments of present invention further provide a method of forming a semiconductor structure. The method includes forming a metal layer on top of a supporting structure; patterning a top portion of the metal layer into a first set of raw metal lines, the first set of raw metal lines being on top of a bottom portion of the metal layer; forming a second set of raw metal lines between the first set of raw metal lines; creating a set of openings between the first set of raw metal lines and the second set of raw metal lines; and etching the bottom portion of the metal layer, via the set of openings, to expose the supporting structure and create a first set of metal lines of a first type and a second set of metal lines of a second type, where the first set of metal lines is made from the second set of raw metal lines and the bottom portion of the metal layer, and wherein the second set of metal lines is made from the first set of raw metal lines and the bottom portion of the metal layer. By patterning the top portion of the metal layer into the first set of raw metal lines, embodiments of present invention enables the etching of the bottom portion of the metal line through a set of high aspect ratio openings, later, to form the first and the second set of metal lines.

In one embodiment, forming the metal layer comprises forming a layer of ruthenium through a physical-vapor-deposition (PVD) process.

In another embodiment, forming the second set of raw metal lines includes selectively growing a set of ruthenium metal lines from the bottom portion of the metal layer between the first set of raw metal lines through a chemical-vapor-deposition (CVD) process.

In yet another embodiment, the first set of raw metal lines includes a first type of ruthenium having a first impurity level and the second set of raw metal lines comprises a second type of ruthenium having a second impurity level, the first impurity level being lower than the second impurity level.

According to one embodiment, the method further includes, before forming the second set of raw metal lines, forming sidewall spacers at sidewalls of the first set of raw metal lines, the sidewall spacers separating the first set of raw metal lines from the second set of raw metal lines.

In one embodiment, creating the set of openings includes selectively removing the sidewall spacers between the first set of raw metal lines and the second set of raw metal lines to expose the bottom portion of the metal layer.

According to another embodiment, the method further includes selectively removing one of the metal lines of the first set or the second set to create a trench opening exposing the supporting structure, and subsequently filling the trench opening with a dielectric material to form a dielectric trench pillar.

According to yet another embodiment, the method further includes selectively removing a hard mask on top of one of the metal lines of the first set or a capping layer on top of one of the metal lines of the second set to create a via opening exposing the one of the metal lines of the first set or the second set, and subsequently filling the via opening with ruthenium to form a topvia.

### BRIEF DESCRIPTION OF THE DRAWINGS

The present invention will be understood and appreciated more fully from the following detailed description of embodiments of present invention, taken in conjunction with accompanying drawings of which:

FIGS. 1-13 are demonstrative illustrations of cross-sectional views of a semiconductor structure in different steps of manufacturing thereof according to embodiments of present invention; and

FIG. 14 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

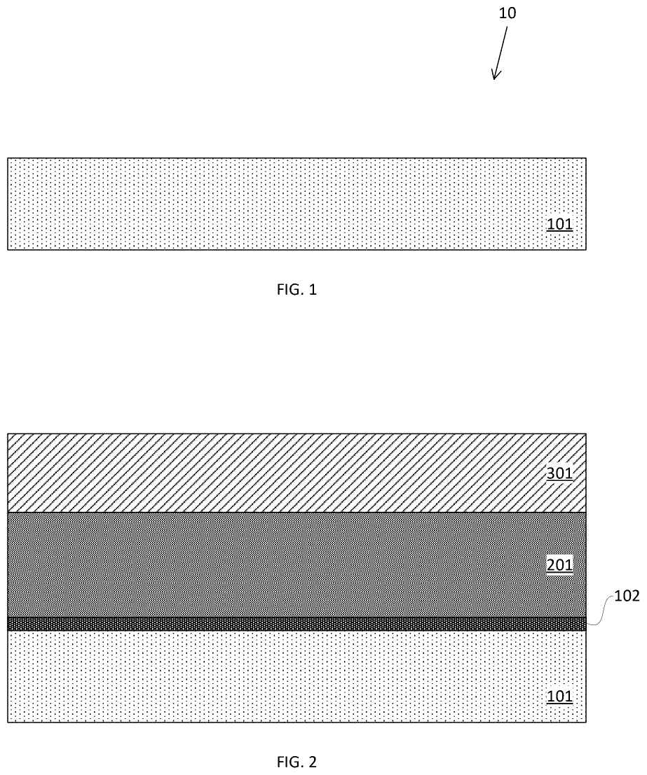

FIG. 1 is a demonstrative illustration of a cross-sectional view of a semiconductor structure in a step of manufacturing thereof according to one embodiment of present invention. More particularly, embodiments of present invention provide forming a semiconductor structure 10 by receiving or providing a supporting structure 101. The supporting structure 101 may be a semiconductor substrate, an active or passive device layer on top of a semiconductor substrate, or an interlevel dielectric (ILD) layer on top of an active or passive device layer or on top of a semiconductor substrate. The ILD layer may additionally include one or more interconnect structures. The semiconductor substrate may be a silicon substrate, a silicon-germanium substrate, a silicon-on-insulator (SOI) substrate, or other suitable substrate.

FIG. 2 is a demonstrative illustration of a cross-sectional view of a semiconductor structure in a step of manufacturing thereof according to one embodiment of present invention. More particularly, following the step illustrated in FIG. 1, embodiments of present invention provide forming an adhesion liner 102, such as a layer of titanium-nitride (TiN) or tantalum-nitride (TaN), covering the supporting structure 101 and then forming a metal layer 201 on top of the adhesion liner 102. The metal layer 201 may be a layer of ruthenium (Ru), molybdenum (Mo), rhodium (Rh), iridium (Ir), nickel (Ni), aluminum (Al), or other suitable metal or metallic material. In one embodiment, the metal layer 201 may be a layer of Ru and may be formed through a physical-vapor-deposition (PVD) process. Next, a hard mask layer 301 may be formed on top of the metal layer 201. The hard mask layer 301 may be a layer of silicon-nitride (SiN), silicon-oxide (SiO₂), silicon-boron carbonitride (SiBCN), silicon-oxycarbonitride (SiOCN), or other suitable materials.

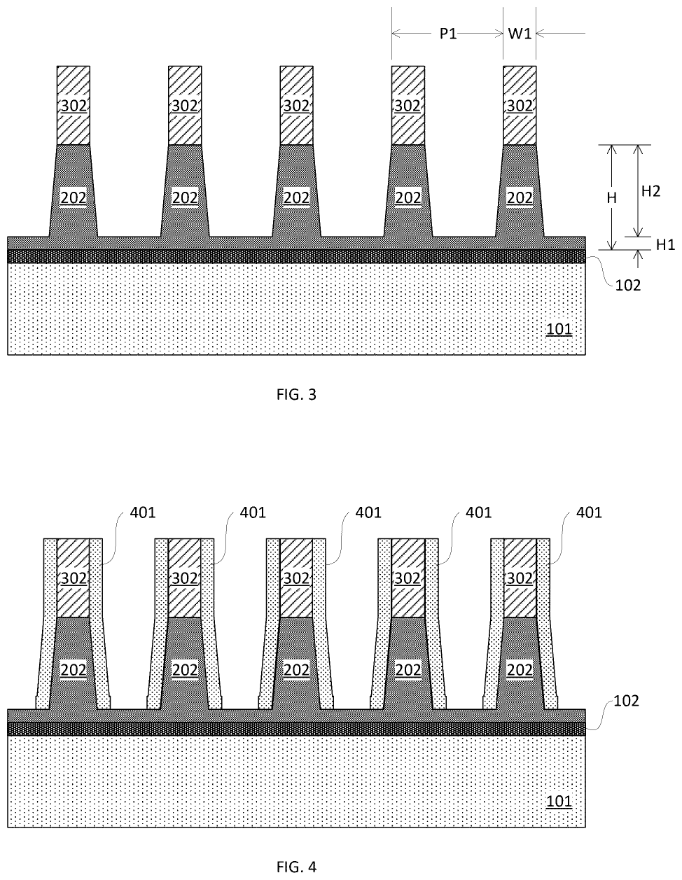

FIG. 3 is a demonstrative illustration of a cross-sectional view of a semiconductor structure in a step of manufacturing thereof according to one embodiment of present invention. More particularly, following the step illustrated in FIG. 2, embodiments of present invention provide forming a hard mask 302 from the hard mask layer 301 through, for example, a lithographic patterning and etching process. The hard mask 302 may include a pattern representing, for example, a plurality of metal lines. The pattern of the hard mask 302 may subsequently be transferred onto the underneath metal layer 201 to create a first set of raw metal lines 202. More particularly, with the hard mask 302 covering the metal layer 201, a top portion of the metal layer 201 may be selectively etched thereby creating the first set of raw metal lines 202. In the meantime, a bottom portion of the metal layer 201 is left un-etched. In other words, the first set of raw metal lines 202 may be created to be on top of the bottom portion of the metal layer 201.

While the first set of raw metal lines 202 may have a thickness H2 ranging from about 10 nm to about 100 nm, the bottom portion of the metal layer 201, which is left un-etched, may have a thickness H1 ranging from about 1 nm to about 10 nm such that, in one embodiment, it may be as thin as 1 nm. The bottom portion of the metal layer 201 may be used as a seed layer in a subsequent process of forming a second set of raw metal lines as being described below in more details. By the nature of etching process, the first set of raw metal lines 202 may be formed to have a trapezoidal shape with slanted sidewalls, with a wide bottom and a narrow top. The first set of raw metal lines 202 may remain conductively connected by the remaining bottom portion of the metal layer 201.

According to one embodiment, the metal layer 201 may have a total thickness H ranging from about 11 nm to about 110 nm, the hard mask 302 may have a width W1 ranging from about 5 nm to about 20 nm, and the hard mask 302 may have a pitch size P1 ranging from about 10 nm to about 50 nm. The pitch size P1 may be made twice a pitch size of the targeted metal lines of a metal level under manufacturing. The doubling of the pitch size P1 significantly relaxed the stringent requirement on the quality of the hard mask 302, thereby enables the patterning of the metal layer 201 with a relatively tall height without hard mask clogging that would, otherwise, impact the etching of the metal layer 201.

FIG. 4 is a demonstrative illustration of a cross-sectional view of a semiconductor structure in a step of manufacturing thereof according to one embodiment of present invention. More particularly, following the step illustrated in FIG. 3, embodiments of preset invention provide forming sacrificial sidewall spacers 401 at sidewalls of the first set of raw metal lines 202 and the hard masks 302 on top thereof. For example, a conformal dielectric layer of dielectric material such as, for example, SiN, SiO₂, SiBCN, SiOCN, or other suitable materials may first be formed through a conformal deposition process such as, for example, an atomic-layer-deposition (ALD) process, a chemical-vapor-deposition (CVD) process, or a PVD process, to cover the first set of raw metal lines 202, the exposed bottom portions of the metal layer 201 between the first set of raw metal lines 202, and the hard masks 302. Next, a directional etching process may be applied to etch and remove horizontal portions of the conformal dielectric layer thereby leaving only vertical portions of the conformal dielectric layer at sidewalls of the first set of raw metal lines 202 and the hard masks 302. The vertical portions of the conformal dielectric layer thereby form the sacrificial sidewall spacers 401. In one embodiment, the sacrificial sidewall spacers 401 may be made of a material different from a material of the hard mask 302 for the purpose of enabling a selective etch process later.

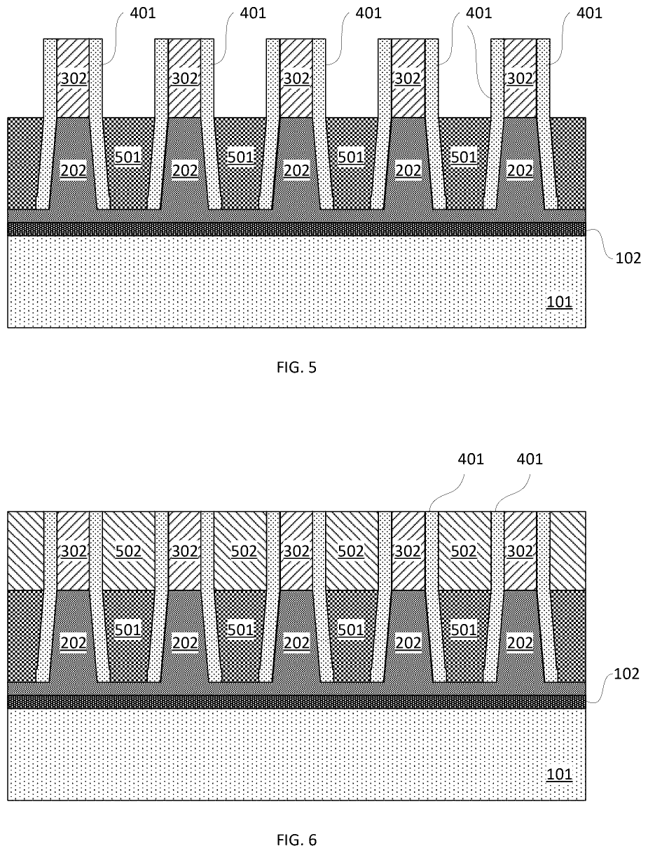

FIG. 5 is a demonstrative illustration of a cross-sectional view of a semiconductor structure in a step of manufacturing thereof according to one embodiment of present invention. More particularly, following the step illustrated in FIG. 4, embodiments of present invention provide forming a second set of raw metal lines 501 between the first set of raw metal lines 202. The second set of raw metal lines 501 may be made of Ru, Mo, Rh, Ir, Ni, Al, or other suitable materials and may be formed through a selective metal growth process. For example, when the metal layer 201 is a layer of Ru, the second set of raw metal lines 501 may be formed in a liner-less Ru growth process such as a CVD process. Ru may selectively grow from the bottom portion of the metal layer 201, which serves as a Ru seed layer. In the selective metal growth process, Ru may not grow from other materials such as the sacrificial sidewall spacers 401 and the hard masks 302, both of which are dielectric materials. The second set of raw metal lines 501 may be grown to have a height that is substantially same as the height H2 of the first set of raw metal lines 202. However, embodiments of present invention are not limited in this aspect and the first and the second set of raw metal lines may be formed to have different heights as well.

The second set of raw metal lines 501 may have slanted sidewalls, following the contour of the sacrificial sidewall spacers 401, to have a trapezoidal shape. The trapezoidal shape of the second set of raw metal lines 501 may have a wide top surface and a narrow bottom surface, which complements to the trapezoidal shape of the first set of raw metal lines 202 that has a wide bottom surface and a narrow top surface.

FIG. 6 is a demonstrative illustration of a cross-sectional view of a semiconductor structure in a step of manufacturing thereof according to one embodiment of present invention. More particularly, following the step illustrated in FIG. 5, embodiments of present invention provide forming a capping layer 502 on top of the second set of raw metal lines 501 by depositing a dielectric material covering the second set of raw metal lines 501 between the sacrificial sidewall spacers 401 that are at the sidewalls of the first set of raw metal lines 202. A chemical-mechanical-polishing (CMP) process may subsequently be applied to planarize a top surface of the capping layer 502 and expose the sacrificial sidewall spacers 401. In one embodiment, the capping layer 502 may be made of a dielectric material different from that of the hard masks 302 as well as the sacrificial sidewall spacers 401. Using a different dielectric material for the capping layer 502 enables a selective etch process among the capping layer 502, the hard masks 302, and the sacrificial sidewall spacers 401 for forming one or more topvias and/or one or more dielectric trench pillars later as being described below in more details.

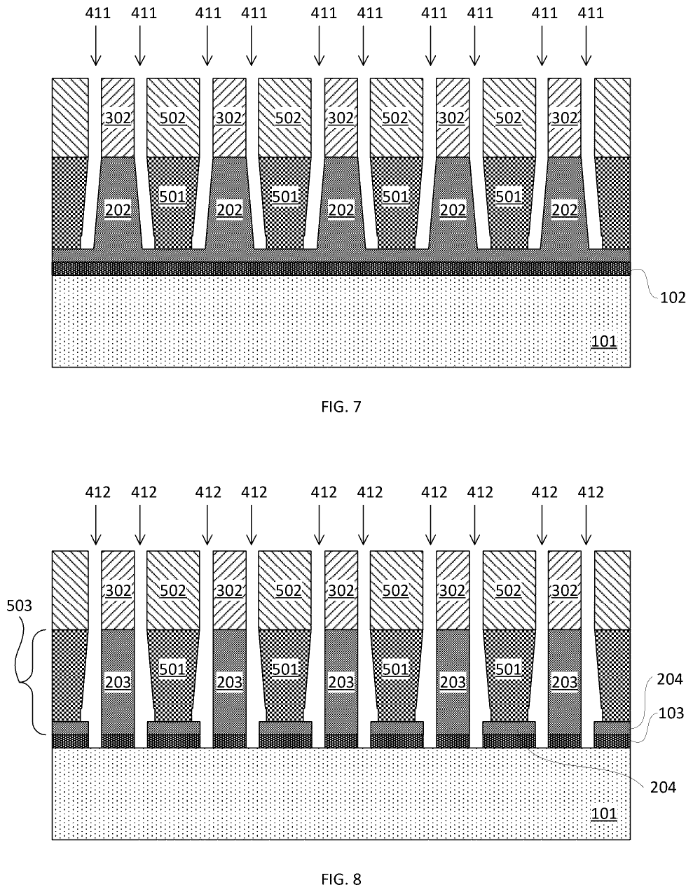

FIG. 7 is a demonstrative illustration of a cross-sectional view of a semiconductor structure in a step of manufacturing thereof according to one embodiment of present invention. More particularly, following the step illustrated in FIG. 6, embodiments of present invention provide selectively removing the sacrificial sidewall spacers 401 that separates the first set of raw metal lines 202 from the second set of raw metal lines 501, thereby creating a set of openings 411 that expose the bottom portion of the metal layer 201, and more particularly portions of the bottom portion of the metal layer 201 between the first and the second set of raw metal lines 202 and 501. The set of openings 411 may also expose, to a certain extent, the slanted sidewalls of the first set of raw metal lines 202.

FIG. 8 is a demonstrative illustration of a cross-sectional view of a semiconductor structure in a step of manufacturing thereof according to one embodiment of present invention. More particularly, following the step illustrated in FIG. 7, embodiments of present invention provide selectively etching the exposed bottom portion of the metal layer 201 and possibly portions, such as sidewalls, of the first set of raw metal lines 202. The etching may be made through the set of openings 411 in a directional and selective etch process until the underneath supporting structure 101 is exposed. For example, a reactive-ion-etch (RIE) process may be used and the RIE etch process may etch through the bottom portion of the metal layer 201, which is generally thin and may thus be easily etched even through an opening such as the set of openings 411 that has an aspect ratio as high as 20.

The etching process may thus create a first type of metal lines such as a first set of metal lines 503 and a second type of metal lines such as a second set of metal lines 203. The first set of metal lines 503 of the first type may include a first section 204 and a second section 501 on top of the first section 204, where the second section 501 may be the second set of raw metal lines 501. The first section 204 may be made from a portion of the bottom portion of the metal layer 201, through the etching process. The first section 204 may have a first width and the second section 501 may have a second width at a top thereof and a third width at a bottom thereof, and the first width and the second width may be larger than the third width. The second set of metal lines 203 of the second type may have a single section and have substantially linear sidewall, thereby having substantially uniform width.

In one embodiment, the first section 204 of the first set of metal lines 503 may be made of a first type of ruthenium that, as is described above, may be formed through a PVD process. The first type of ruthenium may thus have a first impurity level. The second section 501 of the first set of metal lines 503 may be made of a second type of ruthenium that, as is described above, may be formed through a selective metal growth process such as a CVD process. The second type of ruthenium may thus have a second impurity level, and the first impurity level is lower than the second impurity level.

On the other hand, the second set of metal lines 203 may be made entirely from the metal layer 201, including both the top portion and the bottom portion of the metal line. Therefore, the second set of metal lines 203 may be made of the first type of ruthenium that is formed through a PVD process to have the first impurity level. The second set of metal lines 203 does not include the second type of ruthenium formed through a CVD process. In other words, the second set of metal lines 203 is devoid of the second type of ruthenium.

The RIE etch process, through the set of openings 411, may further etch through the adhesion liner 102, thereby transforming the set of openings 411 into a set of openings 412 that expose the underneath supporting structure 101. The first set of metal lines 503 may be separated from the second set of metal lines 203 by the set of openings 412. The adhesion liner 102 may be etched and patterned into a set of adhesion layer 103 underneath the first section 204 of the first set of metal lines 503 or underneath the second set of metal lines 203.

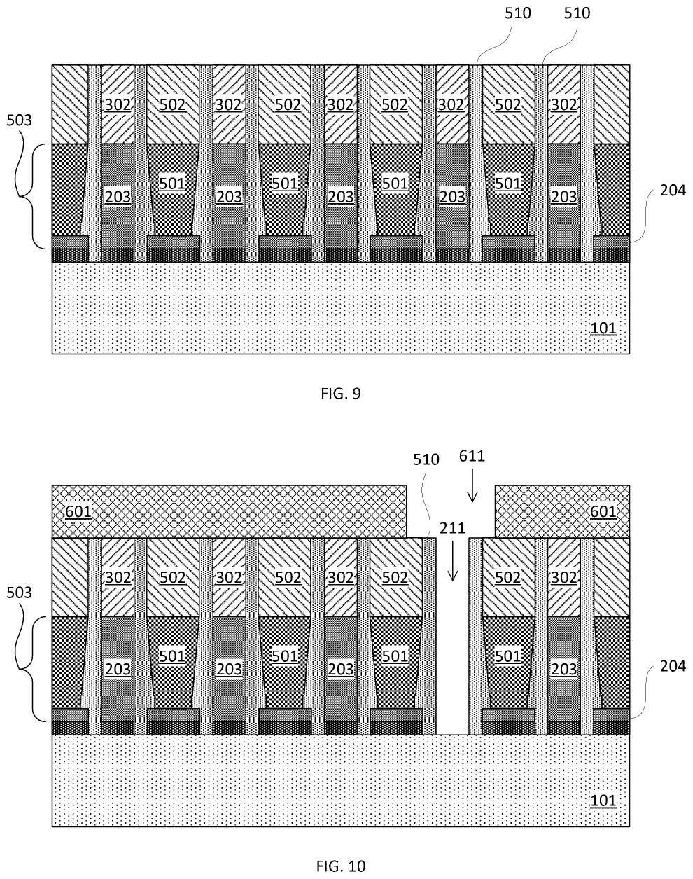

FIG. 9 is a demonstrative illustration of a cross-sectional view of a semiconductor structure in a step of manufacturing thereof according to one embodiment of present invention. More particularly, following the step illustrated in FIG. 8, embodiments of present invention provide filling the set of openings 412 with a dielectric material and then applying a chemical-mechanical-polishing (CMP) process to planarize the top surface of the dielectric material to form a dielectric layer 510. The dielectric layer 510 separates and insulates the first set of metal lines 503 from the second set of metal lines 203.

FIG. 10 is a demonstrative illustration of a cross-sectional view of a semiconductor structure in a step of manufacturing thereof according to one embodiment of present invention. More particularly, following the step illustrated in FIG. 9, embodiments of present invention provide removing and/or replacing one or more of the first type of metal lines 503 and one or more of the second type of metal lines 203 to form one or more dielectric trench pillars.

For example, as a non-limiting example illustrated in FIG. 10, embodiments of present invention provide creating a trench opening in a process of forming a dielectric trench pillar in a location of one of the second set of metal lines 203. An organic planarization (OPL) layer 601 may first be formed, for example through a spin-on process or other suitable approaches, on top of the hard masks 302 and the capping layer 502. An opening 611 may be created in the OPL layer 601 to expose one of the hard masks 302 that is on top of one of the second set of metal lines 203. By strategically applying the etch selectivity among the hard masks 302, the dielectric layer 510, and the capping layer 502, the exposed hard mask 302 may be selectively removed through a selective etch process. Next, the metal line exposed by the removal of the hard mask 302 may be removed as well through a selective etch process. The removal of the hard mask 302 and the metal line underneath thereof creates a trench opening 211 in the dielectric layer 510. The trench opening 211 may expose the underneath supporting structure 101.

Although not explicitly illustrated here, in another embodiment one or more of the first set of metal lines 503 of the first type may be removed in a similar manner as being described above, such as through one or more selective etch processes, to create one or more trench openings. The one or more trench openings may be used to form one or more dielectric trench pillars in locations of the one or more of the first set of metal lines 503.

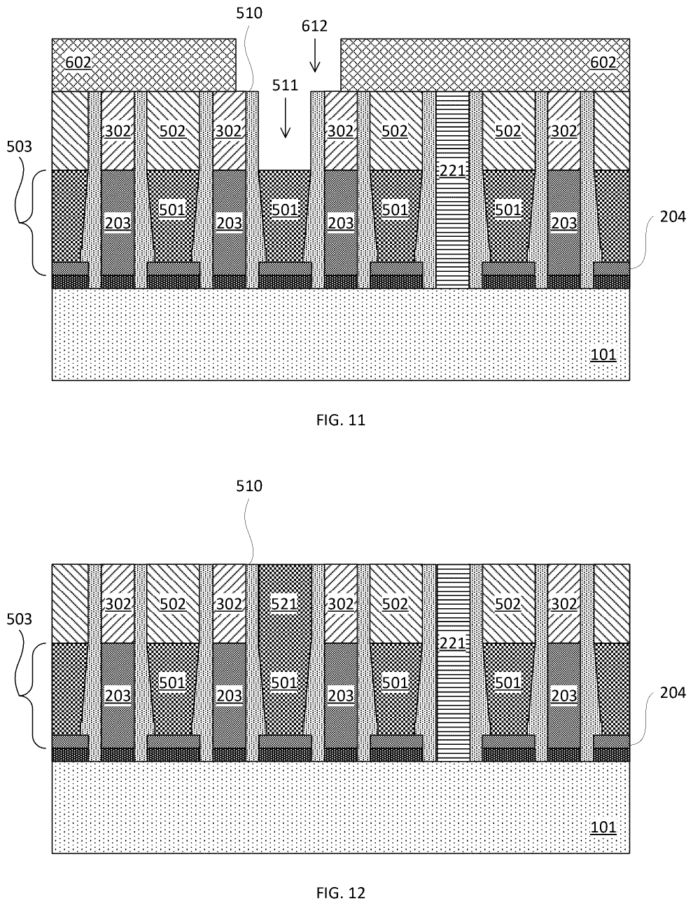

FIG. 11 is a demonstrative illustration of a cross-sectional view of a semiconductor structure in a step of manufacturing thereof according to one embodiment of present invention. More particularly, following the step illustrated in FIG. 10, embodiments of present invention provide filling the trench opening 211 with a dielectric material, such as SiO₂, SIN, SiBCN, SiOCN, or other suitable dielectric materials to form a dielectric trench pillar 221. The dielectric trench pillar 221, as is illustrated in FIG. 11, may be formed adjacent to and between a first and a second metal line of the first set of metal lines 503 of the first type. The first and the second metal lines of the first type may be mirror-symmetric to the dielectric trench pillar 221. Similarly, a dielectric trench pillar may be formed between a first and a second metal line of the second set of metal lines 203 of the second type.

Following the formation of the dielectric trench pillar 221, a CMP process may be applied to planarize a top surface of the dielectric trench pillar 221 to be coplanar with rest of the semiconductor structure 10. Subsequently, an OPL layer 602 may be formed on top of the structure such as on top of the dielectric trench pillar 221, the dielectric layer 510, and one or more of the capping layers 502. An opening 612 may be created in the OPL layer 602 through a lithographic pattering process. The opening 612 may expose one of the capping layers 502. Next, the exposed capping layer 502 may be removed through a selective etch process to expose the underneath one of the first set of metal lines 503, thereby creating a via opening 511.

FIG. 12 is a demonstrative illustration of a cross-sectional view of a semiconductor structure in a step of manufacturing thereof according to one embodiment of present invention. More particularly, following the step illustrated in FIG. 11, embodiments of present invention filling the via opening 511 with a conductive material to form a topvia 521. In one embodiment, the conductive material may be, for example, Ru, Mo, Rh, Ir, Ni, Al, or other suitable materials and may be formed, for example, through a selective metal growth process or a liner-less growth process such as a CVD process. More particularly, by forming the topvia 521 with ruthenium in a CVD process, the ruthenium of the topvia 521 may have an impurity level that is larger than that a ruthenium formed through a PVD process such as the impurity level in the ruthenium of the second set of metal lines 203 or the ruthenium of the second section 204 of the first set of metal lines 503.

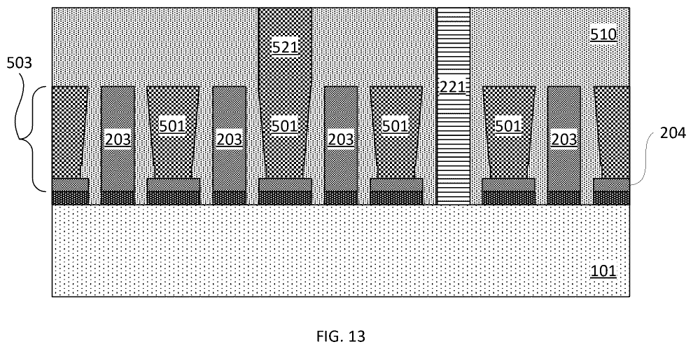

FIG. 13 is a demonstrative illustration of a cross-sectional view of a semiconductor structure in a step of manufacturing thereof according to one embodiment of present invention. More particularly, following the step illustrated in FIG. 12, embodiments of present invention provide, optionally, selectively removing the hard masks 302 and the capping layer 502 that are still remaining on top of the first and the second set of metal lines 503 and 203. Embodiments of present invention then provide filling openings created by the removal of the hard masks 302 and the capping layers 502 with another type of dielectric material, such as the dielectric material of the dielectric layer 510.

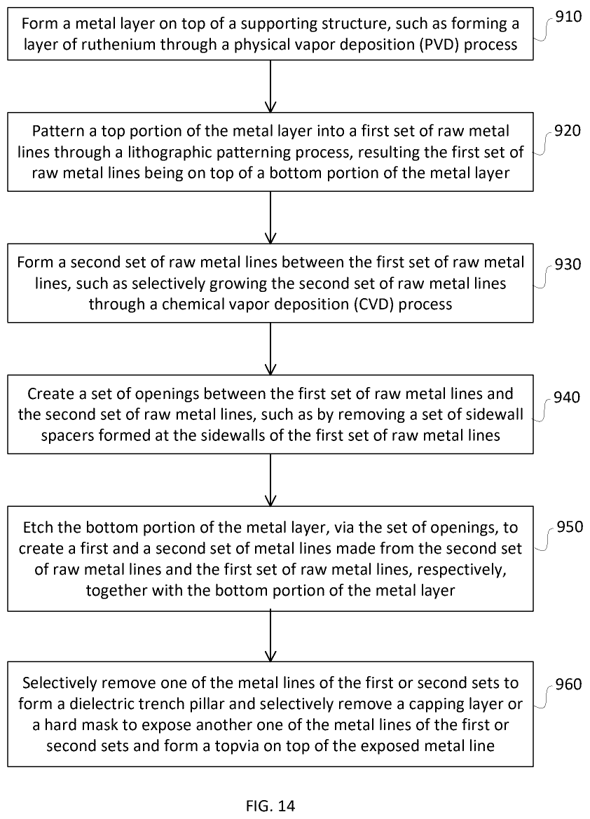

FIG. 14 is a demonstrative illustration of a flow-chart of a method of manufacturing a semiconductor structure according to embodiments of present invention. The method includes (910) forming a metal layer on top of a supporting structure such as forming a layer of ruthenium through a physical vapor deposition (PVD) process; (920) patterning a top portion of the metal layer into a first set of raw metal lines through a lithographic patterning process, resulting the first set of raw metal lines being on top of a bottom portion of the metal layer; (930) forming a second set of raw metal lines between the first set of raw metal lines such as selectively growing the second set of raw metal lines through a chemical vapor deposition (CVD) process; (940) creating a set of openings between the first set of raw metal lines and the second set of raw metal lines such as by removing a set of sidewall spacers formed at the sidewalls of the first set of raw metal lines; (950) etching the bottom portion of the metal layer, via the set of openings, to create a first set of metal lines made from the second set of raw metal lines and the bottom portion of the metal layer and create a second set of metal lines made from the first set of raw metal lines and the bottom portion of the metal layer; and (960) selectively removing one of the metal lines of the first or the second set to form a dielectric trench pillar and selectively removing a capping layer or a hard mask to expose another one of the metal lines of the first or the second set and form a topvia on top of the exposed metal line.

Various examples may possibly be described by one or more of the following features in the following numbered clauses:

Clause 1: A semiconductor structure comprising a metal level comprising a first metal line of a first type, wherein the first metal line of the first type has a first section and a second section on top of the first section, the first section has a first width, the second section has a second width at a top surface and a third width at a bottom surface, and the first width and the second width are larger than the third width.

Clause 2: The semiconductor structure of clause 1, wherein the first section of the first metal line comprises a first type of ruthenium having a first impurity level and the second section of the first metal line comprises a second type of ruthenium having a second impurity level, the first impurity level being lower than the second impurity level.

Clause 3: The semiconductor structure of clause 1, further comprising a dielectric trench pillar and the metal level further comprising a second metal line of the first type, the dielectric trench pillar being adjacent to and between the first and the second metal line, wherein the first and the second metal line are positioned mirror-symmetric with respect to the dielectric trench pillar.

Clause 4: The semiconductor structure of clause 3, wherein a height of the dielectric trench pillar is higher than a height of the first and the second metal line.

Clause 5: The semiconductor structure of clause 2, wherein the metal level further comprises a second metal line of a second type that is different from the first type, the second metal line comprises the first type of ruthenium and is devoid of the second type of ruthenium.

Clause 6: The semiconductor structure of clause 5, further comprising a dielectric trench pillar and the metal level further comprising a third metal line of the second type, the dielectric trench pillar being adjacent to and between the second and the third metal line, wherein the dielectric trench pillar has a height that is higher than a height of the second and the third metal line.

Clause 7: The semiconductor structure of clause 5, wherein the metal level further comprises a third metal line of the second type and a fourth metal line of the first type, the fourth metal line being adjacent to and between the second and the third metal line.

Clause 8: The semiconductor structure of clause 7, further comprising a topvia directly on top of the fourth metal line of the first type, wherein the topvia comprises the second type of ruthenium.

Clause 9: The semiconductor structure of clause 5, further comprising a topvia directly on top of the second metal line of the second type, wherein the topvia comprises the second type of ruthenium.

Clause 10: A method comprising forming a metal layer on top of a supporting structure; patterning a top portion of the metal layer into a first set of raw metal lines, the first set of raw metal lines being on top of a bottom portion of the metal layer; forming a second set of raw metal lines between the first set of raw metal lines; creating a set of openings between the first set of raw metal lines and the second set of raw metal lines; and etching the bottom portion of the metal layer, via the set of openings, to expose the supporting structure and create a first set of metal lines of a first type and a second set of metal lines of a second type, wherein the first set of metal lines is made from the second set of raw metal lines and the bottom portion of the metal layer, and wherein the second set of metal lines is made from the first set of raw metal lines and the bottom portion of the metal layer.

Clause 11: The method of clause 10, wherein forming the metal layer comprises forming a layer of ruthenium through a physical-vapor-deposition (PVD) process.

Clause 12: The method of clause 10, wherein forming the second set of raw metal lines comprises selectively growing a set of ruthenium metal lines from the bottom portion of the metal layer between the first set of raw metal lines through a chemical-vapor-deposition (CVD) process.

Clause 13: The method of clause 10, wherein the first set of raw metal lines comprises a first type of ruthenium having a first impurity level and the second set of raw metal lines comprises a second type of ruthenium having a second impurity level, the first impurity level being lower than the second impurity level.

Clause 14: The method of clause 10, further comprising, before forming the second set of raw metal lines, forming sidewall spacers at sidewalls of the first set of raw metal lines, the sidewall spacers separating the first set of raw metal lines from the second set of raw metal lines.

Clause 15: The method of clause 14, wherein creating the set of openings comprises selectively removing the sidewall spacers between the first set of raw metal lines and the second set of raw metal lines to expose the bottom portion of the metal layer.

Clause 16: The method of clause 10, further comprising selectively removing one of the metal lines of the first set or the second set to create a trench opening exposing the supporting structure, and subsequently filling the trench opening with a dielectric material to form a dielectric trench pillar.

Clause 17: The method of clause 10, further comprising selectively removing a hard mask on top of one of the metal lines of the first set or a capping layer on top of one of the metal lines of the second set to create a via opening exposing the one of the metal lines of the first set or the second set, and subsequently filling the via opening with ruthenium to form a topvia.

Clause 18: A semiconductor structure comprising a metal level on top of a supporting structure, the metal level including a first set of metal lines of a first type and a second set of metal lines of a second type, wherein a metal line of the first type has a first section and a second section on top of the first section, the first section comprises a first type of ruthenium having a first impurity level and the second section comprises a second type of ruthenium having a second impurity level, the first impurity level is lower than the second impurity level, and where a metal line of the second type comprises the first type of ruthenium and is devoid of the second type of ruthenium.

Clause 19: The semiconductor structure of clause 18, further comprising a topvia directly on top of the metal line of the first type, wherein the topvia comprises the second type of ruthenium.

Clause 20: The semiconductor structure of clause 18, wherein the first section has a first width, the second section has a second width at a top surface and a third width at a bottom surface, and the first width and the second width are larger than the third width.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a metal level comprising a first metal line of a first type,
wherein the first metal line of the first type has a first section and a second section on top of the first section, the first section has a first width, the second section has a second width at a top surface and a third width at a bottom surface, and the first width and the second width are larger than the third width.

2. The semiconductor structure of claim 1, wherein the first section of the first metal line comprises a first type of ruthenium having a first impurity level and the second section of the first metal line comprises a second type of ruthenium having a second impurity level, the first impurity level being lower than the second impurity level.

3. The semiconductor structure of claim 1, further comprising a dielectric trench pillar and the metal level further comprising a second metal line of the first type, the dielectric trench pillar being adjacent to and between the first and the second metal line, wherein the first and the second metal line are positioned mirror-symmetric with respect to the dielectric trench pillar.

4. The semiconductor structure of claim 3, wherein a height of the dielectric trench pillar is higher than a height of the first and the second metal line.

5. The semiconductor structure of claim 2, wherein the metal level further comprises a second metal line of a second type that is different from the first type, the second metal line comprises the first type of ruthenium and is devoid of the second type of ruthenium.

6. The semiconductor structure of claim 5, further comprising a dielectric trench pillar and the metal level further comprising a third metal line of the second type, the dielectric trench pillar being adjacent to and between the second and the third metal line, wherein the dielectric trench pillar has a height that is higher than a height of the second and the third metal line.

7. The semiconductor structure of claim 5, wherein the metal level further comprises a third metal line of the second type and a fourth metal line of the first type, the fourth metal line being adjacent to and between the second and the third metal line.

8. The semiconductor structure of claim 7, further comprising a topvia directly on top of the fourth metal line of the first type, wherein the topvia comprises the second type of ruthenium.

9. The semiconductor structure of claim 5, further comprising a topvia directly on top of the second metal line of the second type, wherein the topvia comprises the second type of ruthenium.

10. A method comprising:
forming a metal layer on top of a supporting structure;
patterning a top portion of the metal layer into a first set of raw metal lines, the first set of raw metal lines being on top of a bottom portion of the metal layer;
forming a second set of raw metal lines between the first set of raw metal lines;
creating a set of openings between the first set of raw metal lines and the second set of raw metal lines; and
etching the bottom portion of the metal layer, via the set of openings, to expose the supporting structure and create a first set of metal lines of a first type and a second set of metal lines of a second type,
wherein the first set of metal lines is made from the second set of raw metal lines and the bottom portion of the metal layer, and wherein the second set of metal lines is made from the first set of raw metal lines and the bottom portion of the metal layer.

11. The method of claim 10, wherein forming the metal layer comprises forming a layer of ruthenium through a physical-vapor-deposition (PVD) process.

12. The method of claim 10, wherein forming the second set of raw metal lines comprises selectively growing a set of ruthenium metal lines from the bottom portion of the metal layer between the first set of raw metal lines through a chemical-vapor-deposition (CVD) process.

13. The method of claim 10, wherein the first set of raw metal lines comprises a first type of ruthenium having a first impurity level and the second set of raw metal lines comprises a second type of ruthenium having a second impurity level, the first impurity level being lower than the second impurity level.

14. The method of claim 10, further comprising, before forming the second set of raw metal lines, forming sidewall spacers at sidewalls of the first set of raw metal lines, the sidewall spacers separating the first set of raw metal lines from the second set of raw metal lines.

15. The method of claim 14, wherein creating the set of openings comprises selectively removing the sidewall spacers between the first set of raw metal lines and the second set of raw metal lines to expose the bottom portion of the metal layer.

16. The method of claim 10, further comprising selectively removing one of the metal lines of the first set or the second set to create a trench opening exposing the supporting structure, and subsequently filling the trench opening with a dielectric material to form a dielectric trench pillar.

17. The method of claim 10, further comprising selectively removing a hard mask on top of one of the metal lines of the first set or a capping layer on top of one of the metal lines of the second set to create a via opening exposing the one of the metal lines of the first set or the second set, and subsequently filling the via opening with ruthenium to form a topvia.

18. A semiconductor structure comprising:
a metal level on top of a supporting structure, the metal level including a first metal line of a first type and a second metal line of a second type,
wherein the first metal line of the first type has a first section and a second section on top of the first section, the first section comprises a first type of ruthenium having a first impurity level and the second section comprises a second type of ruthenium having a second impurity level, the first impurity level is lower than the second impurity level, and wherein the second metal line of the second type comprises the first type of ruthenium and is devoid of the second type of ruthenium.

19. The semiconductor structure of claim 18, further comprising a topvia directly on top of the first metal line of the first type, wherein the topvia comprises the second type of ruthenium.

20. The semiconductor structure of claim 18, wherein the first section has a first width, the second section has a second width at a top surface and a third width at a bottom surface, and the first width and the second width are larger than the third width.
